(19) United States
(12) Patent Application Publication
(10) Pub. No.: US 2009/0121334 A1
(43) Pub. Date: May 14, 2009

(54) MANUFACTURING METHOD OF SEMICONDUCTOR APPARATUS AND SEMICONDUCTOR APPARATUS

(75) Inventors: Kiyoshi Oi, Nagano-shi (JP); Masahiro Sunohara, Nagano-shi (JP); Tomoharu Fujii, Nagano-shi (JP)

Correspondence Address: RANKIN, HILL & CLARK LLP, 38210 Glenn Avenue, WILLOUGHBY, OH, 44094-7808, US

(73) Assignee: SHINKO ELECTRIC INDUSTRIES CO., LTD., Nagano-shi (JP)

(21) Appl. No.: 12/266,075

(22) Filed: Nov. 6, 2008

(30) Foreign Application Priority Data
Nov. 9, 2007 (JP) 2007-292142

(51) Int. Cl. H01L 21/50; H01L 23/04

(52) U.S. Cl. 257/678; 438/122; 257/E21.499; 257/E23.181

(57) ABSTRACT

A required number of wiring layers 32 are formed on a temporary substrate 31 of which thermal expansion coefficient differs from that of a semiconductor chip 38 by 2×10⁻⁶/° C. or less and a part of the wiring layer of the uppermost layer is exposed to an opening part of an insulating layer 36 of the uppermost layer as a pad 34 and a wiring substrate is fabricated and a solder bonding member of the semiconductor chip 38 is brought into contact with the pad 34 of the wiring substrate and reflow is performed and the semiconductor chip 38 is attached to the wiring substrate 36. Thereafter, an outer peripheral part of the attached semiconductor chip 38 is sealed while exposing an upper surface of the semiconductor chip and removing the temporary substrate 31 and then a terminal for external connection is formed on the wiring substrate.

### FIELD OF THE INVENTION

The present invention relates to a manufacturing method of a semiconductor apparatus and more particularly to a manufacturing method capable of providing a semiconductor apparatus without poor connection between a chip and a wiring substrate while using solder and a pitch between connection portions between a semiconductor chip and a wiring substrate being 100 μm or less. The invention relates also to a semiconductor apparatus manufactured by its manufacturing method.

### DESCRIPTION OF RELATED ART

A “semiconductor apparatus” herein is an apparatus in which a semiconductor chip is generally connected to a wiring substrate in which multilayer wiring is formed on an organic core substrate by a build-up method using solder. The semiconductor apparatus is used for connecting the semiconductor chip to an external electrical circuit, for example, an electrical circuit such as a motherboard substrate through the wiring substrate.

An example of fabrication of a conventional semiconductor apparatus will be described with reference to FIGS. 13A to 13C. The semiconductor apparatus is generally fabricated by connecting a semiconductor chip 101 to a wiring substrate 102. As shown in FIG. 13A, the semiconductor chip 101 has solder bumps 111 and is bonded to the wiring substrate 102 by reflow while contacting the solder bumps 111 with pads 112 of the wiring substrate 102. As shown in FIG. 13B, a gap between the semiconductor chip 101 and the wiring substrate is filled with an underfill material 103 and thus the semiconductor apparatus is fabricated. In some cases, a heat spreader 104 (FIG. 13C) is arranged on the chip 101 attached to the wiring substrate 102 in order to dissipate heat generated in the semiconductor chip 101. A heat sink (not shown) for heat dissipation is thereafter bonded to the heat spreader 104.

In fabrication of the semiconductor apparatus, since a semiconductor chip is connected to a wiring substrate by reflow of solder, both of the chip and the wiring substrate thermally expand by heating at the time of reflow and both positions of a pad of the wiring substrate and a solder bump of the chip move from positions before heating. Since thermal expansion coefficient of the wiring substrate (using a resin as a base material) is about ten times higher than a thermal expansion coefficient (about 3×10⁻⁶/° C.) of the chip (generally using silicon as a base material), deviation occurs in the positions of the pad of the wiring substrate and the solder bump of the chip at the time of heating. When a pitch of the pad of the wiring substrate and the solder bump of the chip is large, the deviation of both the positions by thermal expansion can be ignored, however, when the pitch is small (for example, 100 μm or less), the deviation cannot be ignored and connection between the wiring substrate and the chip cannot be made secured.

Also, in order to obtain rigidity in a wiring substrate using a resin as a base material, a core material in which a glass cloth is impregnated with a resin is used in the wiring substrate.

As a result, it becomes difficult to achieve thinning or decrease a design rule in the past semiconductor apparatus.

In Japanese Patent Unexamined Publication JP-A-2006-186321, there is described a manufacturing method of a circuit substrate, in which a wiring layer is formed on a metal plate by a build-up method without using a wiring substrate utilizing a core material and then the metal plate is removed. However, a pitch of a pad in the circuit substrate described in the JP-A-2006-186321 is 1000 μm. In view of such a degree of pitch size, it is unnecessary to consider a difference between the circuit substrate and a semiconductor chip in a thermal expansion coefficient. Also, the JP-A-2006-186321 does not recognize that a problem arises in connection between the circuit substrate and the chip due to thermal expansion at the time of reflow of solder.

In a Japanese Patent Unexamined Publication JP-A-2001-177010, there is described a manufacturing method of a semiconductor device, in which a semiconductor chip is mounted and bonded to a multi layer wiring substrate on a high-rigid support body made of metal by solder reflow, and side surface of the chip, a bonding part between the chip and the wiring substrate and an exposed region of the wiring substrate are covered with insulating resin.

This method using the high-rigid support body can prevent warpage of the wiring substrate resulting from stress occurring by heating at the time of bonding from a difference between the circuit substrate and the chip in a thermal expansion coefficient. However, also, the JP-A-2001-177010 does not recognize that a problem arises in connection between the circuit substrate and the chip due to thermal expansion at the time of reflow of solder.

### SUMMARY OF THE INVENTION

An object of the invention is to provide a manufacturing method of a semiconductor apparatus, in which a pitch between connection portions between a semiconductor chip and a wiring substrate is 100 μm or less, without causing deviation of mutual positions between the semiconductor chip and the wiring substrate.

According to an aspect of the invention, there is provided a manufacturing method of a semiconductor apparatus which includes:

a semiconductor chip and

a wiring substrate which includes a terminal for external and is connected to the semiconductor chip by solder

wherein a pitch between connection portions between the semiconductor chip and the wiring substrate is 100 μm or less and

an upper surface of the semiconductor chip is exposed and an outer peripheral part of the semiconductor chip is sealed with sealing material,

the method including the steps of:

(a) forming a lowermost wiring layer on a temporary substrate of a material in which a difference between a semiconductor chip and the temporary substrate in a thermal expansion coefficient is within 2×10⁻⁶/° C.;

(b) fabricating a wiring substrate by forming a required number of wiring layers on the lowermost wiring layer and exposing a part of the wiring layer of the uppermost layer to an opening part of an insulating layer of the uppermost layer as a pad;

(c) attaching the semiconductor chip to the wiring substrate by bringing a solder bonding member of the semiconductor chip into contact with the pad of the wiring substrate to perform reflow process;

(d) sealing an outer peripheral part of the attached semiconductor chip in a state of exposing the upper surface of the semiconductor chip;

(e) removing the temporary substrate and

(f) forming an insulating layer patterned on the wiring layer exposed by removal of the temporary substrate of the wiring substrate and forming the terminal for external connection in a portion of the wiring layer exposed from an opening part of the insulating layer.

Here, the lowermost wiring layer and the uppermost wiring layer may be the same wiring layer if the total number of the wiring layer is one.

As the temporary substrate, for example, a substrate made of silicon, glass or metal can be used.

A heat spreader connected to an exposed surface of the semiconductor chip may be attached before the step (d). As the heat spreader, a metal cover covering the semiconductor chip from the exposed surface to a side surface. Further, the end of the metal cover can be connected to a ground wiring layer of the wiring substrate and thereby, the heat spreader may be used as an electromagnetic shielding material of the semiconductor chip.

According to another aspect of the invention, there is provided a semiconductor apparatus including:

a semiconductor chip and

a wiring substrate which comprises a terminal for external connection and is connected to the semiconductor chip by solder, wherein

a pitch of between connection portions between the semiconductor chip and the wiring substrate is 100 μm or less and

a metal cover which covers the semiconductor chip and

the end of the metal cover is connected to a ground wiring layer of the wiring substrate.

The semiconductor apparatus of the invention may be constructed so that an outer peripheral part of the metal cover is covered with a sealing material.

According to the invention, a semiconductor apparatus without poor connection between a semiconductor chip and a wiring substrate while making connections between a semiconductor chip and a wiring substrate at a pitch of 100 μm or less using solder can be used.

Also, according to the invention, a wiring substrate in a semiconductor apparatus can be fabricated without using a core material such as a glass cloth impregnated with a resin, so that the semiconductor apparatus of the invention can achieve thinning or decrease a design rule.

### BRIEF DESCRIPTION OF THE DRAWINGS

FIGS. 1A through 1D are first diagrams schematically describing a manufacturing method of a semiconductor apparatus of the invention;

FIGS. 2A through 2C are second diagrams schematically describing the manufacturing method of the semiconductor apparatus of the invention;

FIG. 3 is a diagram schematically describing bonding between a wiring substrate and a semiconductor chip according to a method described in Patent Reference 1 by reflow of solder;

FIG. 4 is a diagram schematically describing bonding between a wiring substrate and a semiconductor chip according to a method of the invention by reflow of solder;

FIG. 5 is a schematic diagram showing a semiconductor apparatus according to the invention;

FIG. 6 is a schematic diagram showing a semiconductor apparatus according to the invention;

FIG. 7 is a schematic diagram showing a semiconductor apparatus according to the invention;

FIG. 8 is a schematic diagram showing a semiconductor apparatus according to the invention;

FIGS. 9A and 9B are schematic diagrams showing a semiconductor apparatus according to the invention;

FIG. 10 is a schematic diagram showing a semiconductor apparatus according to the invention;

FIG. 11 is a schematic diagram showing a semiconductor apparatus according to the invention;

FIG. 12 is a schematic diagram describing a mounted product in which a semiconductor apparatus according to the invention is installed on a mounting substrate and FIGS. 13A through 13C are schematic diagrams describing a conventional semiconductor apparatus and its fabrication.

### DETAILED DESCRIPTION OF THE PREFERRED EMBODIMENTS

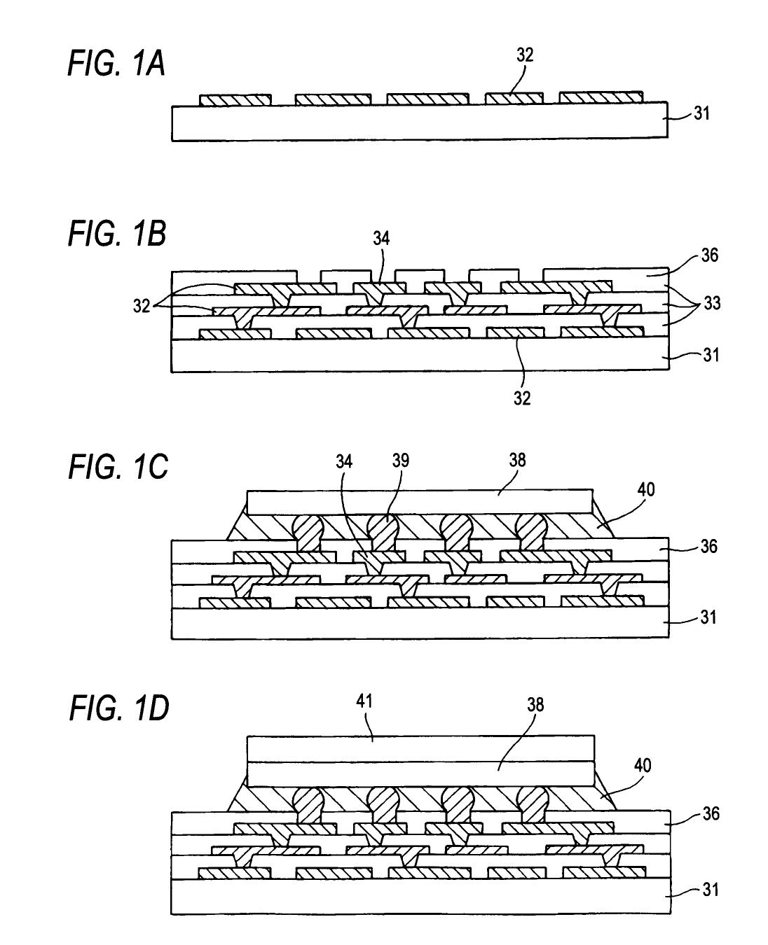

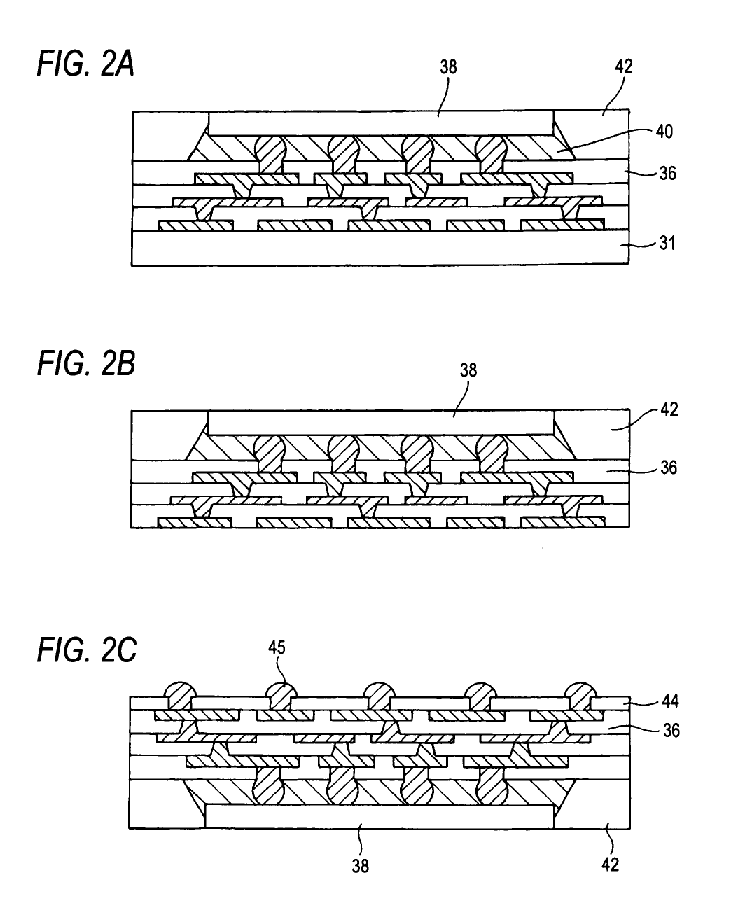

A manufacturing method of a semiconductor apparatus of the invention will be described with reference to FIGS. 1A to 1D and FIGS. 2A to 2C.

As shown in FIG. 1A, a temporary substrate 31 having a thermal expansion coefficient of 5×10⁻⁶/° C. or less which is close to a thermal expansion coefficient (about 3×10⁻⁶/° C.) of a semiconductor chip of silicon is prepared and a lowermost wiring layer 32 is formed on one surface of the temporary substrate 31.

As the temporary substrate 31 satisfying this condition, for example, a substrate made of silicon, glass, etc. can be used. Alternatively, a metal plate etc. (as one example, a plate of Kovar alloy or Fe-42Ni alloy) with a low thermal expansion coefficient satisfying the condition described above can be used.

The wiring layer 32 can be formed by, for example, a patterned copper plated layer. Thickness of the temporary substrate 31 could be designed properly in consideration of handling in a manufacturing process of a semiconductor apparatus and removal of the temporary substrate later. As one example, thickness of about 700 to 800 μm can be adopted when the temporary substrate is made of silicon.

As shown in FIG. 1B, a required number of insulating layers 33 and wiring layers 32 are formed on the lowermost wiring layer 32 of the temporary substrate 31 by a build-up method and a part of the wiring layer of the uppermost layer is exposed as pads 34 and a wiring substrate 36 of the semiconductor apparatus is fabricated on the temporary substrate 31. A pitch of the pads 34 can be set at 100 μm or less, for example, 80 μm. The insulating layer 33 is formed by, for example, an epoxy or polyimide resin and the insulating layer of the uppermost layer, to which the pads 34 are exposed, is formed by a solder resist.

As shown in FIG. 1C, a semiconductor chip 38 in which solder bumps (not shown) as a solder bonding member are formed at a pitch of 80 μm equal to the pitch of the pads 34 of the wiring substrate 36 is attached to the wiring substrate 36 through solder connection portions 39 formed by reflow of the solder bumps. Then, a gap between the substrate 36 and the chip 38 is filled with an underfill material 40. Although both of the temporary substrate 31 and the semiconductor chip 38 thermally expand by heating at the time of the reflow of the solder bumps, since these thermal expansion coefficients are substantially the same (for the temporary substrate of silicon) or are extremely close (for the temporary substrate of glass or a Kovar alloy, etc.), the solder bumps of the chip 38 are bonded to the pads 34 of the wiring substrate 36 without hindrance.

As shown in FIG. 1D, a heat spreader 41 is attached to an upper surface of the semiconductor chip 38 attached. This attachment can be performed by using an adhesive (not shown). Of course, the heat spreader 41 can be omitted and could be attached as necessary. A manufacturing example of a semiconductor apparatus without the heat spreader will hereinafter be described.

As shown in FIG. 2A, an outer peripheral part of the semiconductor chip 38 is sealed with a sealing material 42. The sealing can be performed by a normal method using a material used for the purpose of sealing in a normal semiconductor apparatus. The sealing can be performed by a well-known molding technique such as transfer molding or potting using, for example, an epoxy resin sealing material.

Subsequently, as shown in FIG. 2B, the temporary substrate 31 (FIG. 2A) is removed and one surface of the wiring substrate 36 is exposed. The temporary substrate 31 can be removed by polishing and dry etching when the temporary substrate is made of silicon or glass and can be removed by wet etching when the temporary substrate is made of metal such as a Kovar alloy. When removing the temporary substrate 31 by wet etching, it is preferable to previously dispose a stopper layer for stop etching in a side on which a wiring substrate of the temporary substrate is formed.

As shown in FIG. 2C, a patterned solder resist layer 44 is formed on a surface exposed by removing the temporary substrate of the wiring substrate 36 and solder bumps 45 are formed as terminals for external connection and thus, a semiconductor apparatus for ball grid array (BGA) connection is formed. Instead of the solder bumps 45, a land for land grid array (LGA) connection or a pin for pin grid array (PGA) connection can be formed.

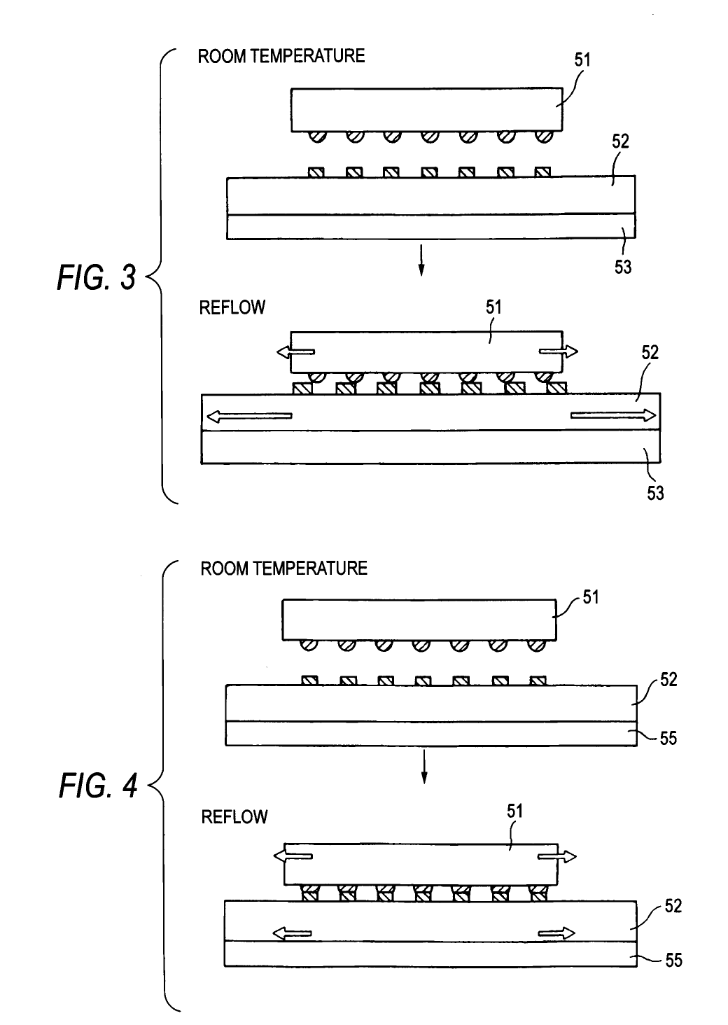

In the JP-A-2001-177010, a semiconductor chip is bonded to a multilayer wiring substrate on a high-rigid support body made of metal by reflow of solder. In the JP-A-2001-177010, a high-rigid metal material is used in the support body for suppressing occurrence of warpage after the reflow of solder. However, as schematically shown in FIG. 3, since a difference between a semiconductor chip 51 and a support body 53 on which a wiring substrate 52 is placed in a thermal expansion coefficient is large, deviation of positions of bumps of the chip and pads of the substrate occurs by the difference between both the semiconductor chip and the support body in thermal expansion at the time of reflow. Here, in FIG. 3, magnitudes of thermal expansion of the chip 51 and the support body 53 are represented by sizes of hollow arrows. As a result, it is difficult to perform mounting process with high-accuracy. Also, when returning the semiconductor device to room temperature, although warpage does not occur due to high-rigidity of the support body, high stress is remained in the semiconductor device.

On contrary, according to the invention, as schematically shown in FIG. 4, since a difference of thermal expansion coefficient between a semiconductor chip 51 and a temporary substrate 55 on which a wiring substrate 52 is placed is small, deviation of positions of bumps of the chip and pads of the substrate by the difference between both the semiconductor chip and the temporary substrate in thermal expansion at the time of reflow does not occur or is an ignorable even though the deviation occurs. Here, in FIG. 4, too, magnitudes of thermal expansion of the chip 51 and the temporary substrate 55 are represented by sizes of hollow arrows. As a result, mounting process can be performed with high-accuracy and also when returning to room temperature, stress does not occur.

An effect of using a temporary substrate in which a difference of thermal expansion coefficient between a semiconductor chip and the temporary substrate is 2×10⁻⁶/° C. or less will herein be described concretely.

Assuming to employ a material of which thermal expansion coefficient differs from that of the silicon chip (about 3×10⁻⁶/° C.) by 13×10⁻⁶/° C. as the temporary substrate (in this example, cupper (Cu) is employed as the temporary substrate), when heating the silicon chip and the temporary substrate from 30° C. to 260° C. (temperature difference is 230° C.), deviation of positions of pads of the substrate and bumps of the chip inside a mounting area of 20×20 mm becomes 230×0.000013×20=0.0598 mm (about 60 μm).

On the other hand, according to the invention, when employing a material of which thermal expansion coefficient differs from that of the silicon chip is 2×10⁻⁶/° C. as the temporary substrate, when heating them in the same manner (temperature difference is 230° C.), deviation of positions of pads of the substrate and bumps of the chip inside a mounting area of 20×20 mm becomes 230×0.000002×20=0.0092 mm (about 10 μm). Thus, according to the invention, since the positional deviation can be suppressed within 10 μm, it is adaptable to connection at a pitch of 100 μm or less.

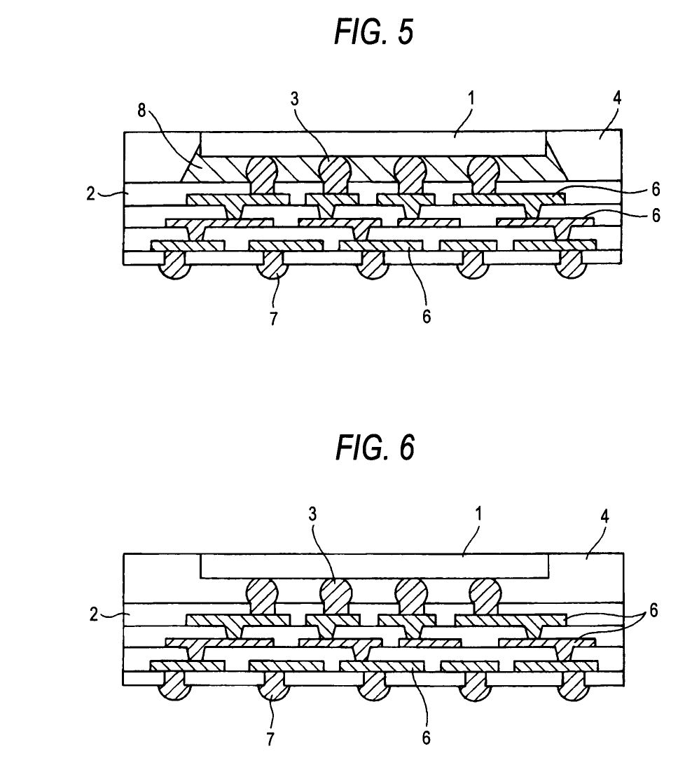

FIG. 5 shows an example of a semiconductor apparatus obtained by the manufacturing method of the invention. In this semiconductor apparatus, a semiconductor chip 1 is connected to a wiring substrate 2 by connection portions 3 by solder at a pitch of 100 μm or less and one surface (surface opposite to a surface bonded to the wiring substrate 2 by solder) of the semiconductor chip 1 is exposed and an outer peripheral part of the semiconductor chip 1 is sealed with a sealing material 4.

In FIG. 5, the wiring substrate 2 having three wiring layers 6 is shown, but the wiring substrate 2 can have any number of wiring layers (one or more). Further, in FIG. 5, the semiconductor apparatus to which one semiconductor chip is attached is shown, but the number of semiconductor chips in the semiconductor apparatus of the invention can also be two or more. Terminals 7 for external connection (for example, solder bumps as shown in FIG. 5) for connecting the semiconductor apparatus to an external electrical circuit, for example, an electrical circuit such as a motherboard substrate are disposed on a surface opposite to a surface to which the semiconductor chip 1 of the wiring substrate 2 is attached.

In the wiring substrate 2 of the semiconductor apparatus according to the invention, a core material in which a glass cloth is impregnated with resin for improving the rigidity is not used. The rigidity of the semiconductor apparatus according to the invention is held by the sealing material 4 of the outer peripheral part of the semiconductor chip.

In the semiconductor apparatus according of FIG. 5, a gap between the semiconductor chip 1 and the wiring substrate 2 is filled with an underfill material 8. In some cases, the gap between the semiconductor chip 1 and the wiring substrate 2 may be filled with a sealing material 4 as shown in FIG. 6 instead of the underfill material 8. Consequently, the number of man-hours of manufacture of the semiconductor apparatus can be reduced.

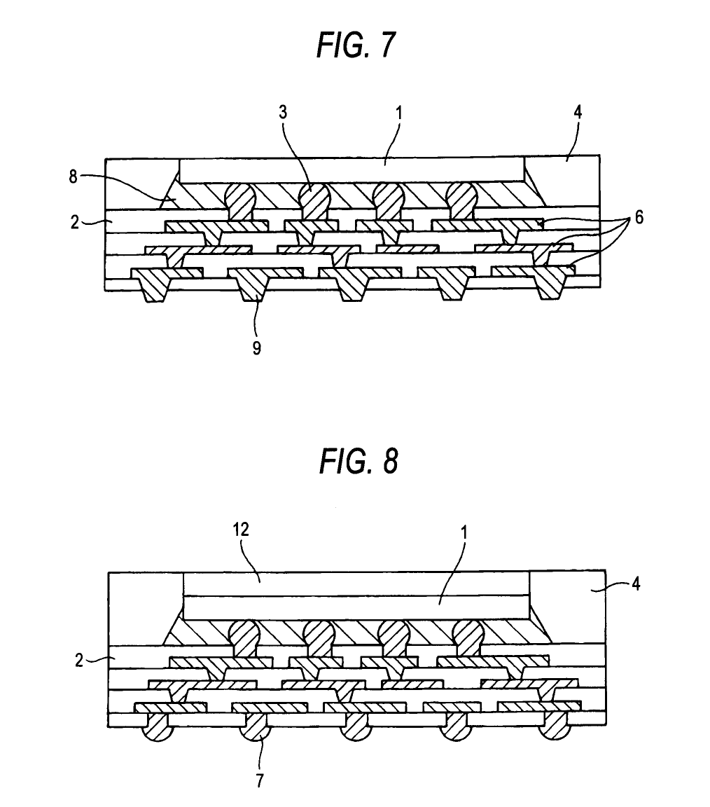

In the semiconductor apparatus according to the invention, a protruded terminal 9 formed by protruding a part of the wiring layer of a wiring substrate 2 as shown in FIG. 7 can also be used as the terminal 7 for external connection instead of the solder bump as illustrated in FIG. 5. The wiring substrate having the protruded terminal 9 can easily be fabricated by forming the lowermost wiring layer 32 using a temporary substrate of, for example, silicon in which a recess (not shown) corresponding to the protruded terminal is previously formed in the step described with reference to FIG. 1A. Thus, the protruded terminal 9 can be formed in the same step as formation of the wiring layer, so that the number of man-hours of manufacture of the semiconductor apparatus can be reduced. A plated layer such as a gold plated layer (not shown) for facilitating connection to an external circuit can be formed on a surface of the protruded terminal 9 formed by a wiring material.

As shown in FIG. 8, a heat spreader (heat dissipation plate) 12 can be attached to a surface exposed from a molding material 4 of a semiconductor chip 1 of the semiconductor apparatus for efficiently dissipating the heat generated in the semiconductor chip. A heat sink (not shown) etc. may be further attached to this heat spreader.

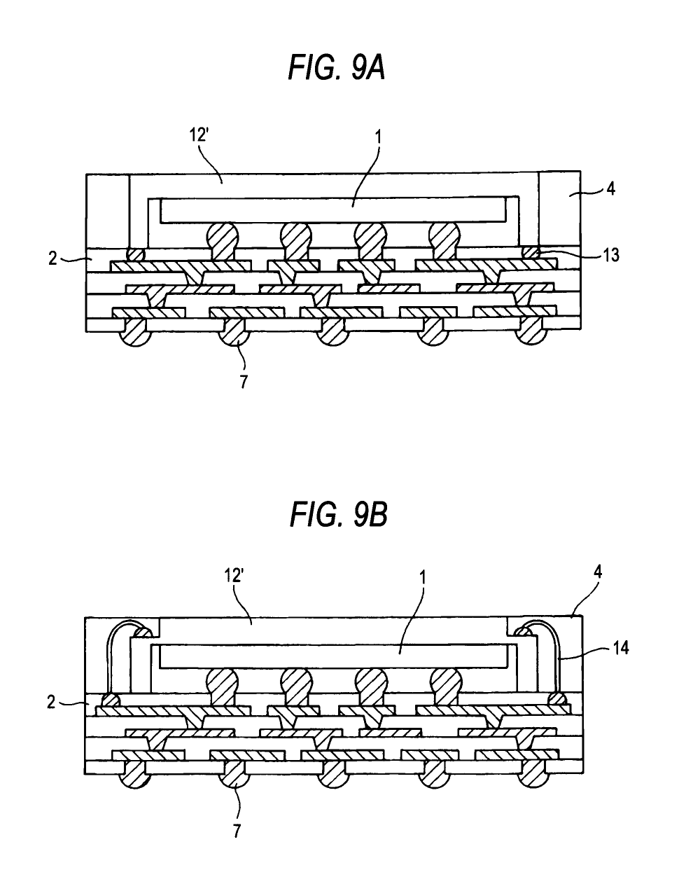

When attaching the heat spreader, its heat spreader can also be used as an electromagnetic shielding material of a semiconductor chip. In this case, as shown in FIGS. 9A and 9B, the periphery of the semiconductor chip is covered with a metal cover 12′ combined with the heat spreader and then the ends of the metal cover 12′ are connected to a ground wiring layer of a wiring substrate 2 by, for example, solder 13 (FIG. 9A) or wires 14 (FIG. 9B).

In the semiconductor apparatus according to the invention, since the thermal expansion coefficient of the semiconductor chip 1 is equal or very close to a thermal expansion coefficient of the temporary substrate used in a manufacturing process of the semiconductor apparatus, deviation of positions of bumps of the chip and bumps of the wiring substrate at the time of reflow heating is reduced and the metal cover 12′ can be installed with high accuracy.

In the semiconductor apparatus having the metal cover 12′ combined with the heat spreader while covering the periphery of the semiconductor as the electromagnetic shielding material, an outer peripheral part of the metal cover 12′ can be covered with a sealing material 4 as shown in FIGS. 9A and 9B. In some cases, the sealing material 4 can be omitted.

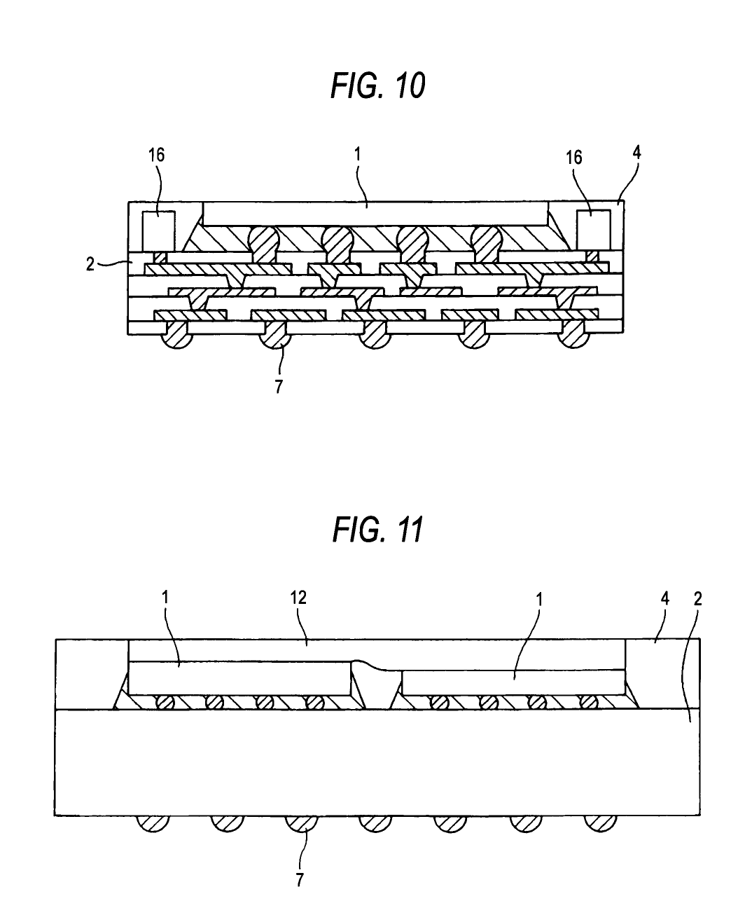

As shown in FIG. 10, in the semiconductor apparatus according to the invention, a passive component (for example, a chip component such as a chip capacitor or a chip resistor), a sensor (for example, a temperature sensor) (not shown) or other components 16 may be installed as necessary.

When a heat spreader 12 is used in the semiconductor apparatus according to the invention to which two or more semiconductor chips 1 are attached, the heat spreader 12 can be common to the two or more semiconductor chips 1 as shown in FIG. 11. Even when there is a difference between the two or more semiconductor chips 1 in height as shown in FIG. 11, the heat spreader 12 capable of being molded by press working of a metal plate can easily absorb the difference in height. In addition, FIG. 11 is simplified by omitting an insulating layer or a wiring layer of a wiring substrate 2 for the sake of simplicity.

In the invention, combinations of the forms of the semiconductor apparatus illustrated above can also be manufactured. For example, a semiconductor apparatus which includes the heat spreader illustrated in FIG. 8 or the metal cover combined with the electromagnetic shielding material and the heat spreader described in FIGS. 9A and 9B and installs the passive component or the sensor, etc. as described in FIG. 10 can be manufactured.

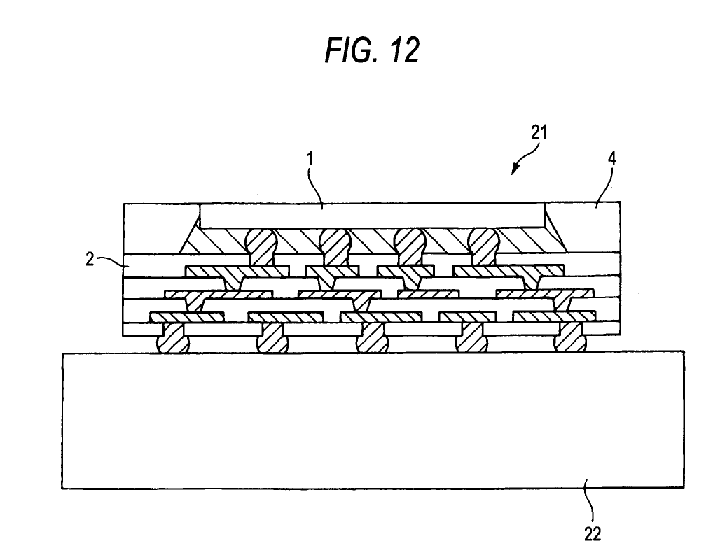

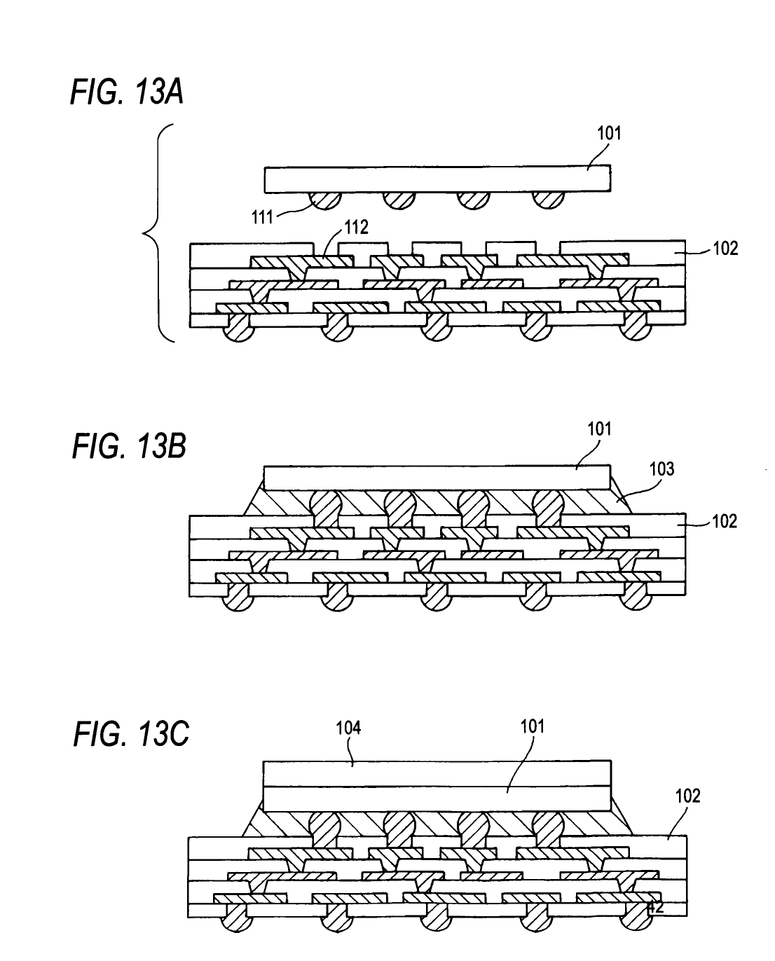

A semiconductor apparatus manufactured by the invention can be installed on a mounting substrate such as a motherboard through terminals for external connection of the semiconductor apparatus. FIG. 12 shows an example of a mounted product in which a semiconductor apparatus 21 according to the invention is installed on a motherboard 22.

While the invention has been described in connection with the exemplary embodiments, it will be obvious to those skilled in the art that various changes and modifications may be made therein without departing from the present invention, and it is aimed, therefore, to cover in the appended claim all such changes and modifications as fall within the true spirit and scope of the present invention.

1. A manufacturing method of a semiconductor apparatus which comprises:
a semiconductor chip and
a wiring substrate which comprises a terminal for external and is connected to the semiconductor chip by solder
wherein a pitch between connection portions between the semiconductor chip and the wiring substrate is 100 μm or less and
an upper surface of the semiconductor chip is exposed and an outer peripheral part of the semiconductor chip is sealed with sealing material,
the method comprising the steps of:
(a) forming a lowermost wiring layer on a temporary substrate of a material in which a difference between a semiconductor chip and the temporary substrate in a thermal expansion coefficient is within 2×10⁻⁶/° C.;
(b) fabricating a wiring substrate by forming a required number of wiring layers on the lowermost wiring layer and exposing a part of the wiring layer of the uppermost layer to an opening part of an insulating layer of the uppermost layer as a pad;
(c) attaching the semiconductor chip to the wiring substrate by bringing a solder bonding member of the semiconductor chip into contact with the pad of the wiring substrate to perform reflow process;
(d) sealing an outer peripheral part of the attached semiconductor chip in a state of exposing the upper surface of the semiconductor chip;
(e) removing the temporary substrate and (f) forming an insulating layer patterned on the wiring layer exposed by removal of the temporary substrate of the wiring substrate and forming the terminal for external connection in a portion of the wiring layer exposed from an opening part of the insulating layer.

2. The manufacturing method of the semiconductor apparatus as set forth in claim 1, wherein
the semiconductor chip is a silicon chip and
thermal expansion coefficient of the temporary substrate is 5×10⁻⁶/° C. or less.

3. The manufacturing method of the semiconductor apparatus as set forth in claim 1, wherein
the temporary substrate is made of silicon, glass or metal.

4. The manufacturing method of the semiconductor apparatus as set forth in claim 1, wherein
a heat spreader connected to an exposed surface of the semiconductor chip is attached before the step (d).

5. The manufacturing method of the semiconductor apparatus as set forth in claim 4, wherein
the heat spreader is a metal cover covering the semiconductor chip from the exposed surface to a side surface and
the end of the metal cover is connected to a ground wiring layer of the wiring substrate.

6. A semiconductor apparatus comprising:
a semiconductor chip and
a wiring substrate which comprises a terminal for external connection and is connected to the semiconductor chip by solder, wherein
a pitch of between connection portions between the semiconductor chip and the wiring substrate is 100 μm or less and
a metal cover which covers the semiconductor chip and
the end of the metal cover is connected to a ground wiring layer of the wiring substrate.

7. The semiconductor apparatus as set forth in claim 6, wherein
an outer peripheral part of the metal cover is covered with a sealing material.

8. The manufacturing method of the semiconductor apparatus as set forth in claim 2, wherein
the temporary substrate is made of silicon, glass or metal.

9. The manufacturing method of the semiconductor apparatus as set forth in claim 8, wherein
a heat spreader connected to an exposed surface of the semiconductor chip is attached before the step (d).

10. The manufacturing method of the semiconductor apparatus as set forth in claim 2, wherein
a heat spreader connected to an exposed surface of the semiconductor chip is attached before the step (d).

11. The manufacturing method of the semiconductor apparatus as set forth in claim 3, wherein
a heat spreader connected to an exposed surface of the semiconductor chip is attached before the step (d).
